(19) United States
(12) Patent Application Publication
(10) Pub. No.: US 2004/0140473 A1
(43) Pub. Date: Jul. 22, 2004

(54) Light emitting diode having distributed electrodes

(75) Inventor: Shi-Ming Chen, Tainan (TW)

Correspondence Address: Richard L. Byrne, 700 Koppers Building, 436 Seventh Avenue, Pittsburgh, PA, 15219-1818, US

(73) Assignees: EPITECH CORPORATION, LTD.; Shi-Ming CHEN

(21) Appl. No.: 10/435,792

(22) Filed: May 12, 2003

(30) Foreign Application Priority Data
Jan. 17, 2003 (TW) 92101049

(51) Int. Cl. H01L 27/15

(52) U.S. Cl. 257/79

(57) ABSTRACT

A light emitting diode (LED) having distributed electrodes is disclosed. The present invention comprises: a semiconductor layer having a first electrical property; a transparent electrode having a second electrical property, wherein the transparent electrode having the second electrical property is located on one portion of the semiconductor layer having the first electrical property; a first distributed electrode having the first electrical property, wherein the first distributed electrode having the first electrical property is located on the other portion of the semiconductor layer having the first electrical property, wherein the first distributed electrode having the first electrical property has at least one first metal electrode pad having the first electrical property and at least one first extension part having the first electrical property, and the at least one first extension part having the first electrical property extends from the at least one first metal electrode pad having the first electrical property; and a second distributed electrode having the second electrical property, wherein the second distributed electrode having the second electrical property is located on the transparent electrode having the second electrical property, wherein the distributed electrode having the second electrical property has at least one second metal electrode pad having the second electrical property and at least one second extension part having the second electrical property, and the at least one second extension part having the second electrical property extends from the at least one metal electrode pad having the second electrical property.

### FIELD OF THE INVENTION

The present invention relates to the structure of a light-emitting diode (LED), to a LED having distributed electrodes.

### BACKGROUND OF THE INVENTION

Recently, there is more emphasis on light-emitting devices formed by semiconductor materials of nitride, such as GaN, AlGaN, InGaN and AlInGaN, etc. Most of the semiconductor layers of the aforementioned-typed light emitting devices are formed electrically non-conductive sapphire substrates, which are different from other light emitting devices using electrically conductive substrates. Since the sapphire substrate is an electrically isolator, electrodes cannot be directly formed on the sapphire substrate. Hence, the electrodes have to directly contact a p-typed semiconductor layer and a n-typed semiconductor layer individually, so as to complete the fabrication of the aforementioned-typed light emitting devices.

Referring to FIG. 1A and FIG. 1B, FIG. 1A and FIG. 1B illustrate respectively a schematic cross-sectional diagram and a schematic top view of a conventional nitride LED, wherein FIG. 1A is a schematic cross-sectional diagram viewed along the a-a′ line shown in FIG. 1B. The structure shown in FIG. 1A and FIG. 1B are formed in accordance with the following process. At first, a buffer layer 20 of low temperature is epitaxially grown on a substrate 10, wherein the material forming the substrate 10 can be such as sapphire, and the material forming the buffer layer 20 can be such as AIN or GaN. Thereafter, a stacked structure is formed epitaxially on the buffer layer 20, the stacked structure comprises in sequence: a semiconductor layer 30 (the material thereof can be such as (AlₓGa₁₋ₓ)_{y}In_{1-y}N (0≦x≦1;0≦y≦1)) having a first electrical property; a first sandwiched layer 40 (the material thereof can be such as (AlₓGa₁₋ₓ)_{y}In_{1-y}N (0≦x≦1;0≦y≦1)) having a first electrical property; an active layer 50 composed of a double hetero-junction structure and a quantum well of (AlₓGa₁₋ₓ)_{y}In_{1-y}N (0≦x≦1;0≦y≦1); a second sandwiched layer 60 (the material thereof can be such as (AlₓGa₁₋ₓ)_{y}In_{1-y}N (0≦x≦1;0≦y≦1)) having a second electrical property; and a contact layer 70 (which is heavily-doped and made of such as (AlₓGa₁₋ₓ)_{y}In_{1-y}N (0≦x≦1;0≦y≦1)) having the second electrical property.

Then, the aforementioned epitaxial layers are etched by using an etching technology, so as to expose a portion of the semiconductor layer 30 having the first electrical property. Thereafter, a first metal electrode pad 90 having the first electrical property is deposited on the exposed portion of the semiconductor layer 30 having the first electrical property by such as thermal evaporation, E-beam or sputtering, etc. Meanwhile, a transparent electrode 100a having the second electrical property and a second metal electrode pad 100b having the second electrical property are deposited sequentially on the contact layer 70 having the second electrical property.

Referring to FIG. 2, FIG. 2 illustrates a schematic top view showing the electrode allocation on the surface of another conventional nitride LED, wherein a transparent electrode 200a having a second electrical property is located on one portion of a semiconductor layer 130 having a first electrical property, and the first metal electrode pad 190 having the first electrical property is located on the other portion of the semiconductor layer 130 having the first electrical property. However, the transparent electrode 200a and the semiconductor layer 130 are not in direct contact, and are separated by an active layer (not shown). Besides, a second metal electrode pad 200b having the second electrical property is located on the transparent electrode 200a having the second electrical property. Moreover, those three first metal electrode pads 190 having the first electrical property are connected by two first electrodes 192 having the first electrical property, and those three second metal electrode pads 200b having the second electrical property are connected by two second electrodes 202 having the second electrical property.

When the aforementioned electrode allocations of the conventional nitride LEDs are applied in a large area LED (i.e. viewed from the top view, the area of the LED is far larger than the area of the first metal electrode pads 190; that of the first electrodes 192; that of the second metal electrode pads 200b; and that of the second electrodes 202), the brightness of the LED cannot be promoted with the increase of the electric current injected. Steigerwald et al. (U.S. Pat. No. 6,397,218; LumiLeds Lighting) disclosed the concept of parallel electrodes suitable for use in the large area LEDs of high power.

### SUMMARY OF THE INVENTION

In view of the aforementioned background of invention, when the electrode allocations of the conventional nitride LEDs are applied in a large area LED, the brightness of the LED cannot be promoted with the increase of the electric current injected. Hence, an object of the present invention is to provide a LED having distributed electrodes, wherein electric current is evenly distributed via the even distribution of electrodes, thereby enhancing the current distribution effect of the large area LED.

Another object of the present invention is to provide a LED having distributed electrodes, wherein at least two metal electrode pads are installed to lower the current density received in each of the metal electrode pads, thereby further promoting the overall electric current sustainable in the metal electrode pads.

Another object of the present invention is to provide a LED having distributed electrodes for promoting the luminance intensity of LED.

According to the aforementioned objects, the present invention provides a LED having distributed electrodes, the LED comprising: a semiconductor layer having a first electrical property; a semiconductor epitaxial structure located on one portion of the semiconductor layer having the first electrical property; a transparent electrode having a second electrical property located on the semiconductor epitaxial structure; a first distributed electrode having the first electrical property, located on the other portion of the semiconductor layer having the first electrical property, wherein the first distributed electrode having the first electrical property has at least one first metal electrode pad having the first electrical property, and at least one first extension part having the first electrical property, the first extension part having the first electrical property extending outwards from the first metal electrode pad having the first electrical property; and a second distributed electrode having the second electrical property, located on the transparent electrode having the second electrical property, wherein the second distributed electrode having the second electrical property has at least one second metal electrode pad having the second electrical property, and at least one second extension part having the second electrical property, the second extension part having the second electrical property extending outwards from the second metal electrode pad having the second electrical property. Further, the aforementioned the first distributed electrode having the first electrical property and the second distributed electrode having the second electrical property can be made of such as Ti, Al, Ni, W or Au, etc. and the alloys thereof. The aforementioned first extension part and second extension part can be in the form of tree-branch distribution. Moreover, the first extension part having the first electrical property and the second extension part having the second electrical property can be arranged in a staggered manner.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1A is a schematic cross-sectional diagram viewed along the a-a′ line shown in FIG. 1B;

FIG. 1B illustrates a schematic top view of a conventional nitride LED;

FIG. 2 illustrates a schematic top view showing the electrode allocation on the surface of another conventional nitride LED;

FIG. 3A illustrates a schematic top view showing the electrode allocation on the surface of a nitride LED according a first preferred embodiment of the present invention;

FIG. 3B is a schematic cross-sectional diagram viewed along the b-b′ line shown in FIG. 3A;

FIG. 4 illustrates a schematic top view showing the electrode allocation on the surface of a nitride LED according a second preferred embodiment of the present invention; and

FIG. 5 is a diagram showing the comparison of luminance intensity among those three LED devices of which the electrode allocations are respectively shown in FIG. 2, FIG. 3A and FIG. 4.

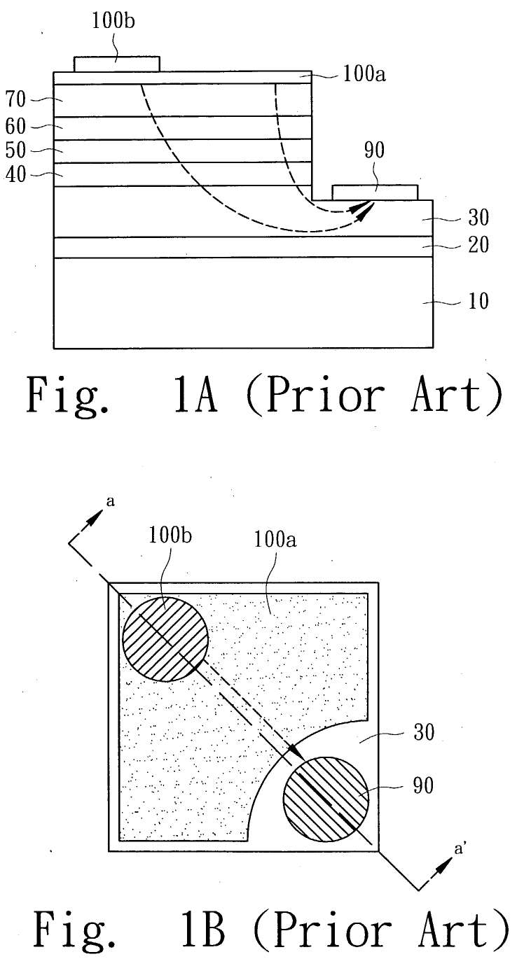

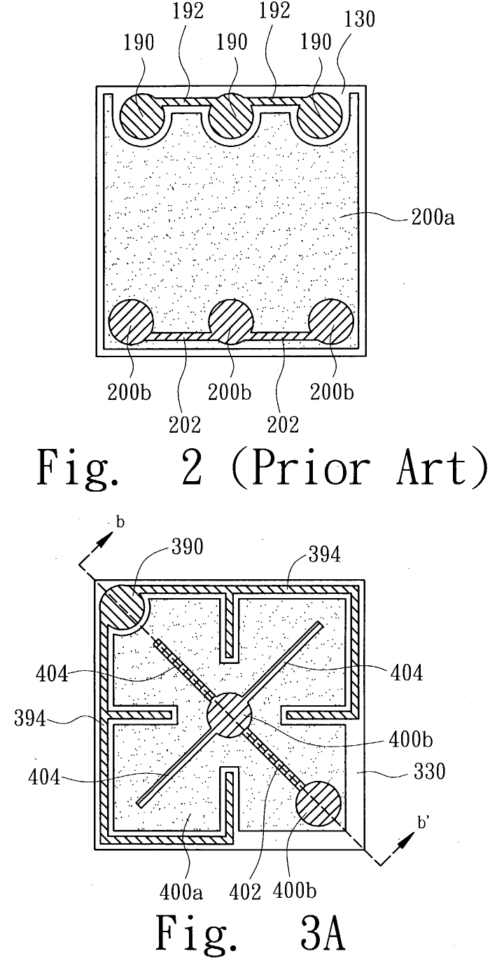

### DETAILED DESCRIPTION OF THE PREFERRED EMBODIMENT

The present invention relates to the structure of a LED having distributed electrodes. As long as LEDs are featured in respectively forming the positive and negative electrodes on the same side of the substrate, then the LEDs are included in the application scope of the present invention, and the present invention is not limited to the LEDs mainly utilizing nitrides.

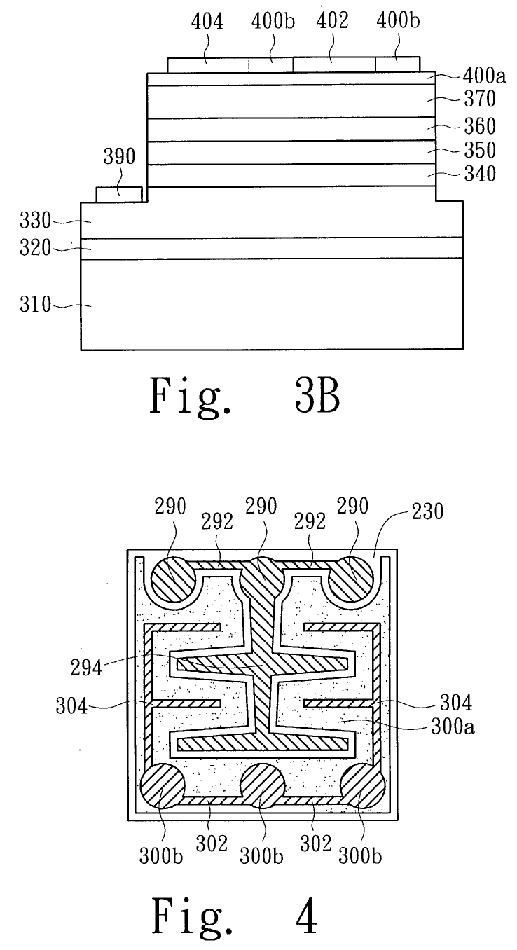

Referring to FIG. 3A and FIG. 3B, FIG. 3A and FIG. 3B illustrate respectively a schematic top view and a schematic cross-sectional diagram of a conventional nitride LED, wherein FIG. 3B is a schematic cross-sectional diagram viewed along the b-b′ line shown in FIG. 3A. The structure shown in FIG. 3A and FIG. 3B are formed in accordance with the following process. At first, a buffer layer 320 of low temperature is epitaxially grown on a substrate 310, wherein the material forming the substrate 310 can be such as sapphire, and the material forming the buffer layer 320 can be such as AlN or GaN. Thereafter, a stacked structure is formed epitaxially on the buffer layer 320, the stacked structure comprises in sequence: a semiconductor layer 330 (the material thereof can be such as (AlₓGa₁₋ₓ)_{y}In_{1-y}N (0≦x≦1;0≦y≦1)) having a first electrical property; a first sandwiched layer 340 (the material thereof can be such as (AlₓGa₁₋ₓ)_{y}In_{1-y}N (0≦x≦1;0≦y≦1)) having a first electrical property; an active layer 350 composed of a double hetero-junction structure and a quantum well of (AlₓGa₁₋ₓ)_{y}In_{1-y}N (0≦x≦1;0≦y≦1); a second sandwiched layer 360 (the material thereof can be such as (AlₓGa₁₋ₓ)_{y}In_{1-y}N (0≦x≦1;0≦y≦1)) having a second electrical property; and a contact layer 370 (which is heavily-doped and made of such as (AlₓGa₁₋ₓ)_{y}In_{1-y}N (0≦x≦1;0≦y≦1)) having the second electrical property. The first electrical property mentioned above can be either p-typed or n-typed, and the second electrical property is opposite to the first electrical property.

Then, the aforementioned epitaxial layers are etched by using an etching technology, so as to expose a portion of the semiconductor layer 330 having the first electrical property. Thereafter, a first metal electrode pad 390 having the first electrical property and a first electrode 394 having the first electrical property are deposited on the exposed portion of the semiconductor layer 330 having the first electrical property by such as thermal evaporation, E-beam or sputtering, etc. Meanwhile, a transparent electrode 400a having the second electrical property; second metal electrode pads 400b having the second electrical property; and second electrodes 402 and 404 having the second electrical property are deposited sequentially on the contact layer 370 having the second electrical property, wherein two second metal electrode pad 400b, shown in FIG. 3A, having the second electrical property are connected via the second electrode 402 having the second electrical property. Further, two sets of first electrode 394 having the first electrical property extend outwards from the first metal electrode pad 390 having the first electrical property, thereby increasing the electrode area having the first electrical property. Similarly, three sets of second electrode 404 having the second electrical property extend outwards from one of the second metal electrode pads 400b having the second electrical property, thereby increasing the electrode area having the second electrical property. Hence, with the application of the present invention, electric current can be distributed more evenly, and the overall current sustainable in the electrodes can be promoted, thereby promoting the luminance intensity of the LED. Moreover, the first metal electrode pad 390 having the first electrical property; the first electrode 394 having the first electrical property; the second metal electrode pad 400b having the second electrical property; the second electrode 402 having the second electrical property; and the second electrode 404 having the second electrical property can be made of the metal materials (such as Ti, Al, Ni, W or Au, etc. and the alloys thereof. Further, such as shown in FIG. 3A, the first electrodes 394 having the first electrical property and the second electrodes 404 having the second electrical property can be arranged in the form of tree-branch distribution or any other forms. As long as the arrangements described above can increase the electrode area, then such arrangements are included in the claimed scope of the present invention. The first electrodes 394 and the second electrodes 404 can be arranged in a staggered manner or any other manners.

Referring to FIG. 4, FIG. 4 illustrates a schematic top view showing the electrode allocation on the surface of a nitride LED according a second preferred embodiment of the present invention. The structure shown in FIG. 4 can be formed in the process similar to that used for forming the structure shown in FIG. 3A. Such as shown in FIG. 4, a transparent electrode 300a having a second electrical property is located on one portion of a semiconductor layer 230 having a first electrical property. As to first metal electrode pads 290 having the first electrical property; first electrodes 292 having the first electrical property; and a first electrode 294 having the first electrical property, they are located on the other portion of a semiconductor layer 230 having a first electrical property. Besides, second metal electrode pads 300b having the second electrical property; and second electrodes 302 and 304 having the second electrical property, are located on the transparent electrode 300a having the second electrical property, wherein three first metal electrode pads 290 having the first electrical property shown in FIG. 4 are connected via two first electrodes 292 having the first electrical property, and three second metal electrode pads 300b having the second electrical property are connected via second electrodes 302 having the second electrical property. Further, the first electrode 294 having the first electrical property extends outwards from one of the first metal electrode pads 290 having the first electrical property. Similarly, the second electrodes 304 having the second electrical property extend outwards from two of the second metal electrode pads 300b having the second electrical property. Thus, the electrode area having the second electrical property can be increased. Moreover, such as shown in FIG. 4, the first electrodes 294 having the first electrical property and the second electrodes 304 having the second electrical property can be arranged in the form of tree-branch distribution or any other forms. As long as the arrangements described above can increase the electrode area, then such arrangements are included in the claimed scope of the present invention. The first electrodes 294 and the second electrodes 304 can be arranged in a staggered manner or any other manners.

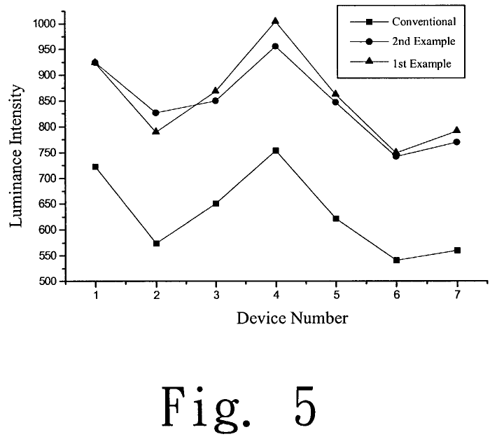

Referring to FIG. 5, FIG. 5 is a diagram showing the comparison of luminance intensity among those three LED devices of which the electrode allocations are respectively shown in FIG. 2, FIG. 3A and FIG. 4. Those three groups of data shown in FIG. 5 are obtained by referencing the electrode allocations respectively shown in FIG. 2, FIG. 3A and FIG. 4, and those three nitride LEDs therein all have the size of 40 mil×40 mil. The horizontal axis shown in FIG. 5 stands for device numbers 1 to 7, i.e. for each type of the nitride LEDs (the conventional type, the first preferred embodiment (example) and the second preferred embodiment (example)), seven different LED devices are used for testing. As to the vertical axis shown in FIG. 5, it stands for the luminance intensity of a LED device. Apparently, from the test results shown in FIG. 5, it can be known that the nitride LEDs having the electrode allocations of the first preferred embodiment and the second preferred embodiment of the present invention, has much stronger luminance intensity than the conventional nitride LED.

To sum up, an advantage of the present invention is to provide a LED having distributed electrodes, wherein electric current is evenly distributed via the even distribution of electrodes, thereby enhancing the current distribution effect of the large area LED.

Another advantage of the present invention is to provide a LED having distributed electrodes, wherein at least two metal electrode pads are installed to lower the current density received in each of the metal electrode pads, so that the overall electric current sustainable in the metal electrode pads are further promoted.

Another advantage of the present invention is to provide a LED having distributed electrodes so as to promote the luminance intensity of LED.

As is understood by a person skilled in the art, the foregoing preferred embodiments of the present invention are illustrated of the present invention rather than limiting of the present invention. It is intended to cover various modifications and similar arrangements included within the spirit and scope of the appended claims, the scope of which should be accorded the broadest interpretation so as to encompass all such modifications and similar structures.

What is claimed is:

1. A light emitting diode (LED) having distributed electrodes, said LED comprising:
a semiconductor layer having a first electrical property;
a semiconductor epitaxial structure located on one portion of said semiconductor layer having said first electrical property;
a transparent electrode having a second electrical property located on said semiconductor epitaxial structure;
a first distributed electrode having said first electrical property, located on the other portion of said semiconductor layer having said first electrical property, wherein said first distributed electrode having said first electrical property has at least one first metal electrode pad having said first electrical property, and at least one first extension part having said first electrical property, said first extension part having said first electrical property extending outwards from said first metal electrode pad having said first electrical property; and
a second distributed electrode having said second electrical property, located on said transparent electrode having said second electrical property, wherein said second distributed electrode having said second electrical property has at least one second metal electrode pad having said second electrical property, and at least one second extension part having said second electrical property, said second extension part having said second electrical property extending outwards from said second metal electrode pad having said second electrical property.

2. The LED having the distributed electrodes according to claim 1, wherein the material forming said semiconductor layer having said first electrical property is (AlₓGa₁₋ₓ)_{y}In_{1-y}N (0≦x≦1;0≦y≦1)).

3. The LED having the distributed electrodes according to claim 1, wherein said semiconductor epitaxial structure is a stacked structure comprising a first sandwiched layer having said electrical property, an active layer, a second sandwiched layer having said second electrical property, and a contact layer having said second electrical property.

4. The LED having the distributed electrodes according to claim 1, wherein said first distributed electrode having said first electrical property and said second distributed electrode having said second electrical property are made of the material selected form a group consisting of Ti, Al, Ni, W and Au.

5. The LED having the distributed electrodes according to claim 1, wherein said first extension part having said first electrical property is in the form of tree-branch distribution.

6. The LED having the distributed electrodes according to claim 1, wherein said second extension part having said second electrical property is in the form of tree-branch distribution.

7. The LED having the distributed electrodes according to claim 1, wherein said first extension part having said first electrical property and said second extension part having said second electrical property are arranged in a staggered manner.

8. A LED having distributed electrodes, said LED comprising:
a substrate;
a semiconductor layer having a first electrical property, located on said substrate;
a semiconductor epitaxial structure located on one portion of said semiconductor layer having said first electrical property;
a transparent electrode having a second electrical property located on said semiconductor epitaxial structure;
a plurality of first metal electrode pads having said first electrical property, located on the other portion of said semiconductor layer having said first electrical property;
at least one first extension electrode having said first electrical property extending outwards from said first metal electrode pads having said first electrical property, thereby forming a first distributed electrode by combining said first extension electrode having said first electrical property, and said first metal electrode pads having said first electrical property;
a plurality of second metal electrode pads having said second electrical property, located on said transparent electrode having said second electrical property; and
at least one second extension electrode having said second electrical property extending outwards from said second metal electrode pads having said second electrical property, thereby forming a second distributed electrode by combining said second extension electrode having said second electrical property, and said second metal electrode pads having said second electrical property.

9. The LED having the distributed electrodes according to claim 8, wherein the material forming said substrate is sapphire.

10. The LED having the distributed electrodes according to claim 8, wherein the material forming said semiconductor layer having said first electrical property is (AlₓGa₁₋ₓ)_{y}In_{1-y}N (0≦x≦1;0≦y≦1)).

11. The LED having the distributed electrodes according to claim 8, wherein said semiconductor epitaxial structure is a stacked structure comprising a first sandwiched layer having said electrical property, an active layer, a second sandwiched layer having said second electrical property, and a contact layer having said second electrical property.

12. The LED having the distributed electrodes according to claim 8, wherein said first distributed electrode having said first electrical property and said second distributed electrode having said second electrical property are made of the material selected form a group consisting of Ti, Al, Ni, W and Au.

13. The LED having the distributed electrodes according to claim 8, further comprising a buffer layer located between said substrate and said semiconductor layer having said first electrical property.

14. The LED having the distributed electrodes according to claim 8, wherein said first extension part having said first electrical property is in the form of tree-branch distribution.

15. The LED having the distributed electrodes according to claim 8, wherein said second extension part having said second electrical property is in the form of tree-branch distribution.

16. The LED having the distributed electrodes according to claim 8, wherein said first extension part having said first electrical property and said second extension part having said second electrical property are arranged in a staggered manner.
